(19) United States
(12) Patent Application Publication
(10) Pub. No.: US 2025/0241107 A1
(43) Pub. Date: Jul. 24, 2025

(54) WIRING SUBSTRATE AND ELECTRONIC DEVICE

(71) Applicants: Hefei BOE Ruisheng Technology Co., Ltd., Hefei, Anhui (CN); BOE Technology Group Co., Ltd., Beijing (CN)

(72) Inventors: Jiawei XU, Beijing (CN); Zouming XU, Beijing (CN); Xiaoxiang ZHANG, Beijing (CN); Xintao WU, Beijing (CN); Jie WANG, Beijing (CN)

(21) Appl. No.: 18/697,998

(22) PCT Filed: Jan. 17, 2023
(86) PCT No.: PCT/CN2023/072708

§ 371 Date: Apr. 2, 2024

(51) Int. Cl. H10H 29/85; H01L 25/16

(52) U.S. Cl. CPC H10H 29/857; H01L 25/167

(57) ABSTRACT

Provided is a wiring substrate. The wiring substrate includes a base substrate, a plurality of first units, a plurality of second pad regions, and a plurality of common voltage signal lines. Each of the plurality of first units includes a plurality of first pad regions, and each of the plurality of first pad regions includes at least one first pad group. Each of the second pad regions includes a plurality of second pads including ground pads and output pads. The plurality of common voltage signal lines are arranged along a first direction and extend along a second direction. The common voltage signal line travels through the first unit and the second pad region. Each of the plurality of common voltage signal lines includes a plurality of first portions and a plurality of second portions. The first portions and the second portions are connected successively in the second direction.

### CROSS-REFERENCE TO RELATED APPLICATION

The present disclosure is a U.S. national stage of international application No. PCT/CN2023/072708, filed on Jan. 17, 2023, the content of which is herein incorporated by reference in its entirety.

### TECHNICAL FIELD

The present disclosure relates to the field of display technologies, and in particular, relates to a wiring substrate and an electronic device.

### BACKGROUND

Micro light-emitting diodes are becoming more and more widely used in the display field due to advantages such as smaller size, ultra-high brightness, and long life.

### SUMMARY

Embodiments of the present disclosure provide a wiring substrate. The wiring substrate includes:
a base substrate;
a plurality of first units arranged in an array along a first direction and a second direction on a side of the base substrate, the first direction being intersected with the second direction, wherein each of the plurality of first units includes a plurality of first pad regions, each of the plurality of first pad regions including at least one first pad group, the first pad group including a first sub-pad and a second sub-pad;
a plurality of second pad regions disposed on a same side of the base substrate as the plurality of first units, wherein each of the plurality of second pad regions includes at least one second pad group, and the second pad group includes a plurality of second pads, the plurality of second pads including ground pads and output pads in one-to-one correspondence to the plurality of first units, each the plurality of first units being connected to one of the output pads; and
a plurality of common voltage signal lines disposed on the same side of the base substrate as the plurality of first units, wherein the plurality of common voltage signal lines are arranged along the first direction and extend along the second direction, each of the plurality of common voltage signal lines travels through the first unit and the second pad region, and each of the plurality of common voltage signal lines includes a plurality of first portions and a plurality of second portions, wherein the first portions and the second portions are successively alternately connected in the second direction, a width of each of the first portions is greater than a width of each of the second portions in the first direction, and each of the second portions travels through the second pad region and is reused as the ground pad.

In some embodiments, the second pad region is disposed within the first unit, and an orthographic projection of the second pad group on the base substrate is not overlapped with an orthographic projection of the first pad region on the base substrate.

In some embodiments, the first portion has a first axis of symmetry extending along the second direction, and the second portion has a second axis of symmetry extending along the second direction, the first axis of symmetry being coincident with the second axis of symmetry.

In some embodiments, the plurality of second pads further include a first power pad, a second power pad, a first address pad, and a second address pad; and

the rest of the second pads other than the ground pad are disposed on two sides of the ground pad in the first direction.

In some embodiments, the first power pad, the second power pad, and one portion of the output pads are disposed on one side of the second portion in the first direction; and the first address pad, the second address pad, and the other portion of the output pads are disposed on the other side of the second portion in the first direction.

In some embodiments, the first power pad, the second power pad, and the portion of the output pads are arranged along the second direction;
in the second direction, the first power pad and the second power pad are disposed on two sides of the portion of the output pads, respectively;
the first address pad, the second address pad, and the other portion of the output pads are arranged along the second direction; and
in the second direction, the first address pad and the second address pad are disposed on two sides of the other portion of the output pads, respectively.

In some embodiments, the wiring substrate further includes: a plurality of first connection leads, a plurality of second connection leads, and a plurality of third connection leads; wherein
in the second direction, one end of the first connection lead is electrically connected to the first power pad of one of adjacent two of the second pad regions, and the other end of the first connection lead is electrically connected to the second power pad of the other of the adjacent two second pad regions;
in the second direction, one end of the second connection lead is electrically connected to the first address pad of one of adjacent two of the second pad regions, and the other end of the second connection lead is electrically connected to the second address pad of the other of the adjacent two second pad regions; and
one end of the third connection lead is electrically connected to the output pad, and the other end of the third connection lead is electrically connected to the first pad region.

In some embodiments, the first connection lead is disposed between the third connection lead and the common voltage signal line; and
the second connection lead is disposed between the third connection lead and the common voltage signal line.

In some embodiments, each of the first pad regions includes a plurality of the first pad groups connected in series.

In some embodiments, the plurality of the first pad groups connected in series are successively arranged along the second direction.

In some embodiments, the plurality of first units successively arranged along the second direction form a first unit column; and the wiring substrate further includes:
a plurality of constant voltage signal lines disposed on the same side of the base substrate as the plurality of first units, wherein the plurality of constant voltage signal lines are arranged along the first direction and extend along the second direction, are disposed on a side of the first unit column, and are electrically connected to at least one of the first unit columns.

In some embodiments, in the first direction, only one of the constant voltage signal lines is present between adjacent two of the first unit columns, and the constant voltage signal line disposed between adjacent two of the first unit columns is electrically connected to the adjacent two first unit columns.

In some embodiments, in the first direction, a width of the constant voltage signal line is equal to the width of the first portion.

In some embodiments, in the first direction, a ratio of the width of the second portion to the width of the first portion is greater than or equal to ⅕ and less than 1.

Some embodiments of the present disclosure provide an electronic device. The electronic device includes a wiring substrate as described, a plurality of electronic elements and a plurality of drive chips that are disposed on a side of the wiring substrate; wherein each of the plurality of electronic elements is electrically connected to the first pad group, and each of the plurality of drive chips is electrically connected to the second pad group.

In some embodiments, the electronic elements are micro-sized inorganic light-emitting diodes.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic structural diagram of a light-emitting substrate according to some embodiments of the present disclosure;

FIG. 2 is a schematic structural diagram of another light-emitting substrate according to some embodiments of the present disclosure;

FIG. 3 is a schematic structural diagram of still another light-emitting substrate according to some embodiments of the present disclosure;

FIG. 4 is a schematic structural diagram of yet still another light-emitting substrate according to some embodiments of the present disclosure; and

FIG. 5 is a schematic structural diagram of yet still another light-emitting substrate according to some embodiments of the present disclosure.

### DETAILED DESCRIPTION

The present disclosure is described in further detail with reference to the accompanying drawings, to clearly present the objects, technical solutions, and advantages of the present disclosure. It should be noted that the dimensions and shapes of the figures in the accompanying drawings do not reflect true proportions and are intended to schematically illustrate the present disclosure only. Obviously, the described embodiments are a portion of the embodiments of the present disclosure and not all of the embodiments. The embodiments and the features in the embodiments of the present disclosure may be combined with each other without conflict. Based on the described embodiments of the present disclosure, all other embodiments obtained by those skilled in the art without the need for creative labor fall within the scope of protection of the present disclosure.

Unless otherwise defined, technical or scientific terms used in the embodiments of the present disclosure shall have ordinary meanings understandable by persons of ordinary skill in the art to which the disclosure belongs. The terms “first,” “second,” and the like used in the embodiments of the present disclosure are not intended to indicate any order, quantity, or importance, but are merely used to distinguish the different components. The terms “comprise,” “include,” and derivatives or variations thereof are used to indicate that the element or object preceding the terms covers the element or object following the terms and its equivalents, and shall not be understood as excluding other elements or objects. The terms “connect,” “contact,” and the like are not intended to be limited to physical or mechanical connections, but may include electrical connections, either direct or indirect connection.

It should be noted that the dimensions and shapes of the figures in the accompanying drawings do not reflect true proportions and are intended only to schematically illustrate the present disclosure. The same or similar referring numerals indicate the same or similar elements or elements having the same or similar function.

In some practices, a wiring substrate of the micro light-emitting diode includes a plurality of constant voltage signal lines and a plurality of common voltage signal lines. In a case where the wiring space of the constant voltage signal lines and the common voltage signal lines is small, i.e., in a case where the line widths of the constant voltage signal lines and the common voltage signal lines are limited, in order to make the constant voltage signal lines and the common voltage signal lines meet the voltage drop demand, it is necessary to arrange the constant voltage signal lines and the common voltage signal lines with a thicker thickness, and it is even necessary to use double-layer wiring, and thus the cost is increased greatly.

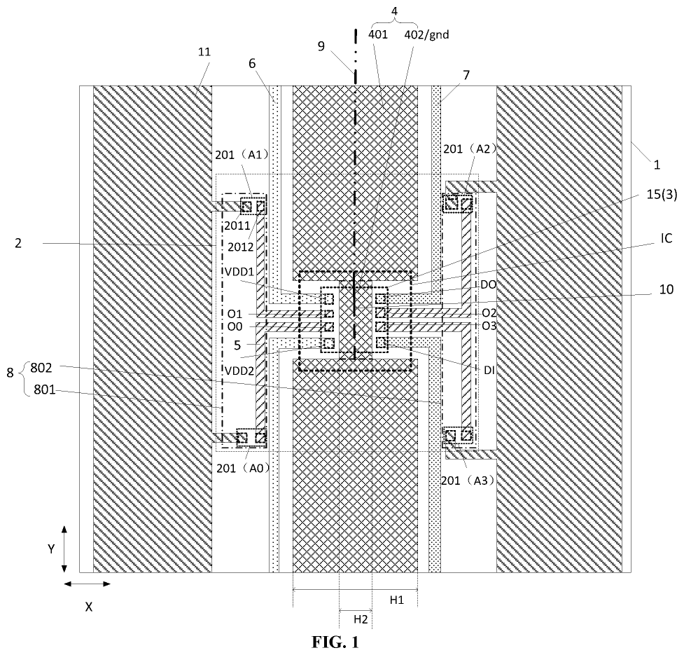

Some embodiments of the present disclosure provide a wiring substrate. As shown in FIG. 1, the wiring substrate includes:
a base substrate 1;
a plurality of first units 2 arranged in an array along a first direction X and a second direction Y on a side of the base substrate 1, wherein the first direction X is intersected with the second direction Y, each of the plurality of first units 2 includes a plurality of first pad regions 201, each of the plurality of first pad regions 201 includes at least one first pad group A, and the first pad group A includes a first sub-pad 2011 and a second sub-pad 2012;
a plurality of second pad regions 3 disposed on the same side of the base substrate 1 as the first unit 2, wherein each of the second pad regions 3 includes at least one second pad group, the second pad group includes a plurality of second pads 2021, the plurality of second pads 2021 include ground pads gnd and output pads 0 that are in one-to-one correspondence to the first units 2, and each of the first units 2 is connected to one of the output pads O; and
a plurality of common voltage signal lines 4 disposed on the same side of the base substrate 1 as the first unit 2, wherein the plurality of common voltage signal lines 4 are arranged along the first direction X and extend along the second direction Y, the common voltage signal line 4 travels through the first unit 2 and the second pad region 3, each of the plurality of common voltage signal lines 4 includes a plurality of first portions 401 and a plurality of second portions 402, the first portions 401 and the second portions 402 are successively alternately connected in the second direction Y, in the first direction X, a width H1 of the first portion 401 is greater than a width H2 of the second portion 402, and the second portion 402 travels through the second pad region 3 and is reused as the ground pad gnd.

It should be noted that the wiring substrate according to some embodiments of the present disclosure is applied to an electronic device. Each first pad group is bound to an electronic element, and the plurality of second pads in the second pad region are bound to a drive chip, such that the electronic element is driven to operate under the control of the drive chip. For example, one of the second pad regions corresponds to one of the first units, and a corresponding drive chip controls the operation of all electronic elements within the first unit corresponding thereto. A region occupied by the plurality of second pads bound to one drive chip is the second pad region, and a region enclosed by the first pad region corresponding to the electronic elements controlled by one drive chip is the first unit. The electronic element is, for example, a light-emitting device.

It should be noted that, in general, a distance between two first pad regions adjacent in the first direction is large. That is, the first unit has sufficient wiring space between two first pad regions adjacent in the first direction, such that the common voltage signal line travels through the first unit but does not interfere with the first pad group. That is, an orthographic projection of the common voltage signal line on the base substrate and an orthographic projection of the first pad group on the base substrate are not overlapped with each other. Moreover, the second portion is reused as the ground pad, and the orthographic projection of the common voltage signal line on the base substrate is not overlapped with an orthographic projection of the remaining second pad other than the ground pad on the base substrate. That is, although the common voltage signal line travels through the second pad region, it does not interfere with the remaining second pads other than the ground pad.

In the wiring substrate according to some embodiments of the present disclosure, the common voltage signal line travels through the first unit and the second pad region. Because there is sufficient wiring space between two first pad regions adjacent in the first direction in the first unit, a width, in the first direction, of the common voltage signal line traveling through the first unit is also arranged to be wide in the case of not interfering with the first pad region. That is, compared to the common voltage signal line arranged in a region between two first units adjacent to each other in the first direction, the maximum width of the common voltage signal line in the first direction is increased, such that a resistance of the common voltage signal line is reduced, and a voltage drop of the common voltage signal line is reduced. In this way, the wiring substrate according to some embodiments of the present disclosure does not need to reduce the voltage drop by increasing the thickness of the common voltage signal line or double-layer wiring, such that the cost is saved. Moreover, the second portion, traveling through the second pad region, of the common voltage signal line is reused as the ground pad, and thus in a case where the electrical connection between the common voltage signal line and the ground pad is achieved, the wiring space is saved.

In specific embodiments, as shown in FIG. 1, an outline of an orthographic projection of the drive chip IC on the base substrate 1 is generally a quadrilateral, such as a rectangle. The second pad of the second pad region 3 is bound to the drive chip IC, therefore, an area of the second pad region 3 needs to be matched with an area of the orthographic projection of the drive chip IC on the base substrate 1, and the orthographic projection of the drive chip IC on the base substrate 1 covers the second pad region 3. Typically, the area of the second pad region is much smaller than an area of the first unit. The distance between two first pad regions adjacent in the first direction is usually greater than 4500 micrometers, and thus the width, in the first direction, of the common voltage signal line traveling through the first unit is arranged to be very wide. A width of the drive chip in the first direction is about 2 mm. Moreover, a size of each second pad in the second pad region needs to be matched with the area of the drive chip, and thus the width, in the first direction, of the second portion that travels through the second pad region and is reused as the ground pad needs to be smaller than the width of the first portion in the first direction. Furthermore, the second portion functions as the ground pad bound to the drive chip, in the second direction a length of the second portion is less than a length of the drive chip, and the length of the drive chip in the second direction is about 2 mm. Accordingly, the length of the second portion is smaller in the second direction. That is, the width and length of the second portion are smaller, and the second portion occupies a smaller portion of the common voltage signal line and has a smaller impact on the impedance of the common voltage signal line.

In some embodiments, as shown in FIG. 1, the plurality of first units arranged along the second direction Y form a first unit column 8. Only one first unit 2 included in the first unit column 8 is shown in FIG. 1.

### The Wiring Substrate Further Includes:

a plurality of constant voltage signal lines 11 disposed on the same side of the base substrate 1 as the first unit 2, wherein the plurality of constant voltage signal lines 11 are arranged along the first direction X and extend along the second direction Y, the constant voltage signal lines 11 are disposed on a side of the first unit column 8, and the constant voltage signal lines 11 are electrically connected to at least one first unit column 8.

It should be noted that in some practices, the region between adjacent two of the first unit columns needs to be provided with the common voltage signal line and the constant voltage signal line. In a case where the wiring space between adjacent two first unit columns is limited, the line widths of the common voltage signal line and the constant voltage signal line are small.

In the wiring substrate according to some embodiments of the present disclosure, the common voltage signal line does not need to be arranged in the region between the first unit columns, such that the wiring space of the constant voltage signal line is increased, and the maximum width of the constant voltage signal line in the first direction is increased, and thus the resistance of the constant voltage signal line is reduced, and the voltage drop of the constant voltage signal line is reduced.

In some embodiments, as shown in FIG. 1, the second pad region 3 is disposed within the first unit 2, and an orthographic projection of the second pad group 202 on the base substrate 1 and an orthographic projection of the first pad region 201 on the base substrate 1 are not overlapped with each other.

It should be noted that because the area of the second pad region is much smaller than the area of the first unit, arranging the second pad region within the first unit does not cause interference with the first pad group of the first unit. In the wiring substrate according to some embodiments of the present disclosure, the second pad region is disposed within the first unit, such that the space utilization of the wiring substrate is improved. There is no need to additionally arrange the second pad region in a region outside the first unit, such that the space is saved, and the number of first units is improved.

In some embodiments, as shown in FIG. 1, the first portion 401 has a first axis of symmetry 9 extending along the second direction Y, and the second portion 402 has a second axis of symmetry 10 extending along the second direction Y. The first axis of symmetry 9 is coincident with the second axis of symmetry 10.

In the wiring substrate according to some embodiments of the present disclosure, in the first direction, the width of the first portion is greater than the width of the second portion, the first axis of symmetry is coincident with the second axis of symmetry, and areas of regions on both sides of the second portion and not exceeding an edge extension line of the first portion is equal. Therefore, both sides of the second portion have sufficient wiring space to arrange the rest of the second pads.

In some embodiments, as shown in FIG. 1, the first unit column 8 includes a first pad region column 801 and a second pad region column 802 that are respectively disposed on both sides of the common voltage signal line 4. Each of the first pad region columns 801 includes a plurality of first pad regions 201 arranged along the second direction Y, and each of the second pad region columns 802 includes a plurality of first pad regions 201 arranged along the second direction Y.

The plurality of second pad regions 3 arranged along the second direction Y form the second pad region column 15. It should be noted that only one second pad region 3 included in the second pad region column 15 is shown in FIG. 1.

Any of the second pad region column 15 is disposed between the first pad region column 801 and the second pad region column 802 included in the first unit column 8.

In some embodiments, the width H2 of the second portion is greater than or equal to 800 micrometers in the first direction.

It should be noted that the width of the second portion is small, therefore, in the case where the size of the drive chip is matched, the wider the width H2 of the second portion, the less the impact on the common voltage signal line impedance.

In some embodiments, in the first direction, a ratio of the width H2 of the second portion 402 to the width H1 of the first portion 401 is greater than or equal to ⅕ and less than 1.

In some embodiments, in the first direction, the width H1 of the first portion is 4500 micrometers, and the width H2 of the second portion is 1006 micrometers.

In some embodiments, in the second direction, the length of the second portion is greater than or equal to 2000 micrometers. In the second direction, a distance between the first portion and its closest second pad is greater than or equal to 200 micrometers. In the second direction, the widths of the respective second pads are equal, and the width of the second pad is greater than or equal to 300 micrometers. In the rest of the second pads other than the second portion, in the second direction, a distance between adjacent two second pads is greater than or equal to 100 micrometers.

In some embodiments, as shown in FIG. 1, the plurality of second pads further include a first power pad VDD1, a second power pad VDD2, a first address pad DI, and a second address pad DO.

The rest of the second pads other than the ground pad gnd are disposed in the first direction X on two sides of the ground pad gnd.

It should be noted that the first pad regions are in one-to-one correspondence to the output pads. That is, the number of output pads is the same as the number of first pad regions included in the first unit. The description of FIG. 1 is given using a scenario where the first unit 2 includes four first pad regions 201 as an example, and accordingly, the second pad region includes four output pads, and the four output pads are O0, O1, O2, and O3. The output pad O0 is electrically connected to the first pad region 201 in the lower-left corner of the first unit 2, the output pad O1 is electrically connected to the first pad region 201 in the upper-left corner of the first unit 2, the output pad O3 is electrically connected to the first pad region 201 in the lower-right corner of the first unit 2, and the output pad O2 is electrically connected to the first pad region 201 in the upper-right corner of the first unit 2. Each of the first pad regions 201 in FIG. 1 includes only one first pad group A, and the first pad groups included in the four first pad regions 201 are A0, A1, A2, and A3, respectively. The output pad O0 is electrically connected to the first pad group A0, the output pad O1 is electrically connected to the first pad group A1, the output pad O2 is electrically connected to the first pad group A2, and the output pad O3 is electrically connected to the first pad group A3 connected.

In specific embodiments, a plurality of second pad regions corresponding to one first unit column are successively cascaded. In two second pad regions adjacent in the second direction, the first power pad of one of the second pad regions is electrically connected to the second power pad of the second pad region of the next cascade, and the second address pad of one of the second pad regions is electrically connected to the second address pad of the second pad region of the next cascade. The first power pad provides the drive chip with an operating voltage and communication data, and the communication data is configured to control the operating state of the corresponding electronic element. A drive signal is a drive current, configured to drive the electronic element electrically connected to the second pad group in which the output pad is located. The drive chip provides the drive chip of the next cascade with an operating voltage and communication data through the second power pad. The output pad outputs the drive signal. The first address pad receives an address signal for gating a drive chip at the corresponding address. The drive chip further generates a relay signal and outputs the relay signal through the second address pad. The relay signal serves as an address signal of the first address pad in the second pad group of the next cascade. The ground pad receives a common voltage signal transmitted by the common voltage signal line.

It should be noted that in a case where the electronic element is a light-emitting device, each of the first pad regions includes at least one first pad group. A region corresponding to the first pad group is regarded as a light-emitting region, and each of the first pad regions corresponds to at least one light-emitting region. Because the first unit includes a plurality of first pad regions, a single drive chip is utilized to drive a plurality of light-emitting regions. Compared with the case where one drive chip drives only one light-emitting region, the number of drive chips is reduced, and thus the cost is saved.

In some embodiments, as shown in FIG. 1, the first power pad VDD1, the second power pad VDD2, and partial output pads O0 and O1 are disposed on one side of the second portion 402 in the first direction X, and the first address pad DI, the second address pad DO, and remaining output pads O2 and O3 are disposed on the other side of the second portion 402 in the first direction X.

In some embodiments, the first power pad VDD1, the second power pad VDD2, and partial output pads O0 and O1 are arranged along the second direction Y.

In the second direction Y, the first power pad VDD1 and the second power pad VDD2 are respectively disposed on two sides of a portion of the output pads O0 and O1.

The first address pad DI, the second address pad DO, and the remaining output pads O2 and O3 are arranged along the second direction Y.

In the second direction Y, the first address pad DI and the second address pad DO are respectively disposed on both sides of remaining output pads O2 and O3.

Therefore, it is convenient to achieve that: the first power pad VDD1 is electrically connected to the second power pad VDD2 of the upper cascade level, the second power pad VDD2 is electrically connected to the first power pad VDD1 of the next cascade, the first address pad DI is electrically connected to the second address pad DO of the upper cascade, and the second address pad DO is electrically connected to the first address pad DI of the next cascade.

In some embodiments, as shown in FIG. 1, the wiring substrate further includes a plurality of first connection leads 6, a plurality of second connection leads 7, and a plurality of third connection leads 5.

In the second direction Y, one end of the first connection lead 6 is electrically connected to the first power pad VDD1 of one of the adjacent two second pad regions 3, and the other end of the first connection lead 6 is electrically connected to the second power pad VDD2 of the other of the adjacent two second pad regions 3.

In the second direction Y, one end of the second connecting lead 7 is electrically connected to the first address pad DI of one of the adjacent two second pad regions 3, and the other end of the second connecting lead 7 is electrically connected to the second address pad DO of the other of the adjacent two second pad regions 3.

One end of the third connection lead 5 is electrically connected to the output pads O0, O1, O2, and O3, and the other end of the third connection lead 5 is electrically connected to the first pad region 201.

In some embodiments, the first connection lead 6 is disposed between the third connection lead 5 and the common voltage signal line 4, as shown in FIG. 1.

The second connection lead 7 is disposed between the third connection lead 5 and the common voltage signal line 4.

In the wiring substrate according to some embodiments of the present disclosure, the first power pad and the second power pad are disposed in the first direction on the same side of the second portion, and the first power pad and the second power pad are disposed in the second direction on both sides of the output pad, such that the first connection lead is provided between the third connection lead and the common voltage signal line, and thus the first power pad is electrically connected to the second power pad of the upper cascade by the first connection lead. Moreover, the first address pad and the second address pad are disposed in the first direction on the same side of the second portion, and the first address pad and the second address pad are disposed in the second direction on both sides of the output pad, such that the second connecting lead is provided between the third connection lead and the common voltage signal line, and thus the first address pad is electrically connected to the second address pad of the upper cascade by the second connecting lead. That is, in the wiring substrate according to some embodiments of the present disclosure, in the second pad region, the wiring difficulty of the various connection leads is reduced by the location of the various second pads.

It should be noted that the description of FIG. 1 is given using a scenario where each of the first pad regions 201 includes only one first pad group A as an example.

In some embodiments, as shown in FIG. 1, the output pad O is electrically connected to the second sub-pad 2012 of one of the first pad groups A in the first pad region 201 by the third connection lead 5. In a case where each of the first pad regions includes only one first pad group, the first sub-pad 2011 is electrically connected to the constant voltage signal line 11, as shown in FIG. 1.

In practical application, each of the first pad regions includes a plurality of first pad groups.

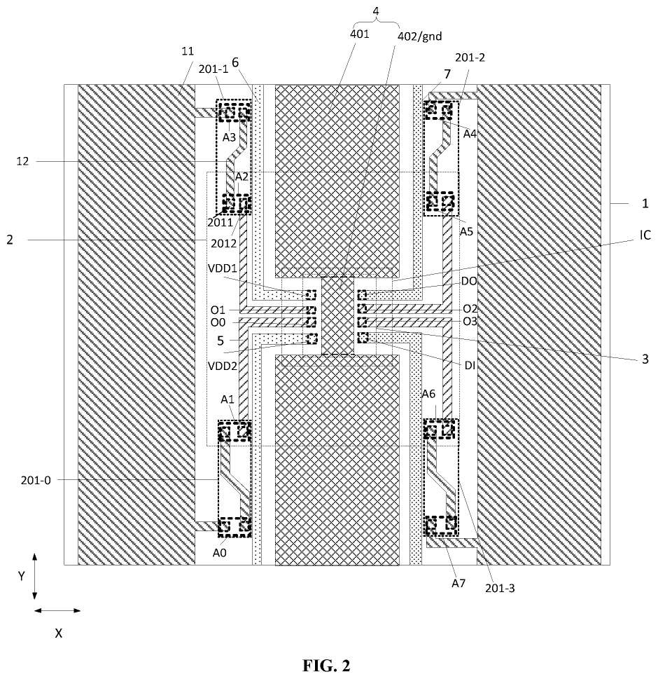

In some embodiments, as shown in FIG. 2, each of the first pad regions 201 includes a plurality of first pad groups A connected in series.

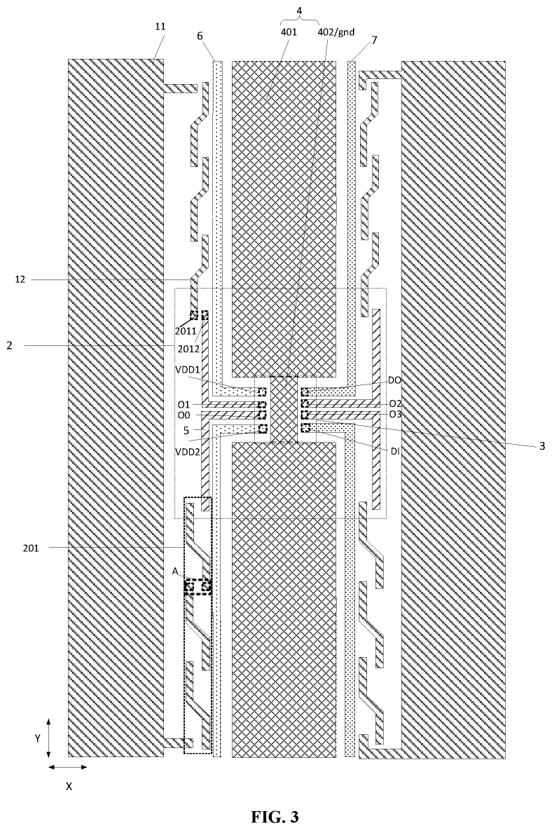

It should be noted that in FIG. 2, the description is given using a scenario where each of the first pad regions includes two first pad groups A connected in series as an example. The first pad region 201-0 at the lower-left corner includes the first pad groups A0 and A1. The first pad region 201-1 at the upper-left corner includes the first pad groups A2 and A3. The first pad region 201-2 at the upper-right corner includes the first pad groups A4 and A5. The first pad region 201-3 at the lower-right corner includes the first pad groups A6 and A7. In some embodiments, each of the first pad regions includes more first pad groups A. For example, as in FIG. 3, each of the first pad regions 201 includes four first pad groups A connected in series.

In the wiring substrate according to some embodiments of the present disclosure, each of the first pad regions includes a plurality of first pad groups, and accordingly, each pad group needs to be bound to a plurality of electronic elements. In a case where the electronic elements are light-emitting devices, a region corresponding to each of the first pad regions includes a plurality of light-emitting devices. That is, the region includes light-emitting regions, which is conducive to reducing power consumption.

In some embodiments, as shown in FIG. 2, in each of the first pad regions 201, the plurality of first pad groups A are connected in series by the fourth connection lead 12. In two of the first pad groups A connected in series by the fourth connection lead 12, one end of the fourth connection lead 12 is electrically connected to the first sub-pad 2011 of one of the first pad groups A, and the other end of the fourth connection lead 12 is electrically connected to the second sub-pad 2012 of the other of the first pad groups A.

In some embodiments, the plurality of first pad groups A connected in series are successively arranged along the second direction Y, as shown in FIG. 2.

In the wiring substrate according to some embodiments of the present disclosure, the plurality of first pad groups in each of the first pad regions are successively arranged along the second direction. Compared to the case in which the plurality of first pad groups are successively arranged along the first direction, this arrangement avoids reducing the wiring space of the common voltage signal lines in the first direction and thus avoids increasing the voltage drop of the common voltage signal lines.

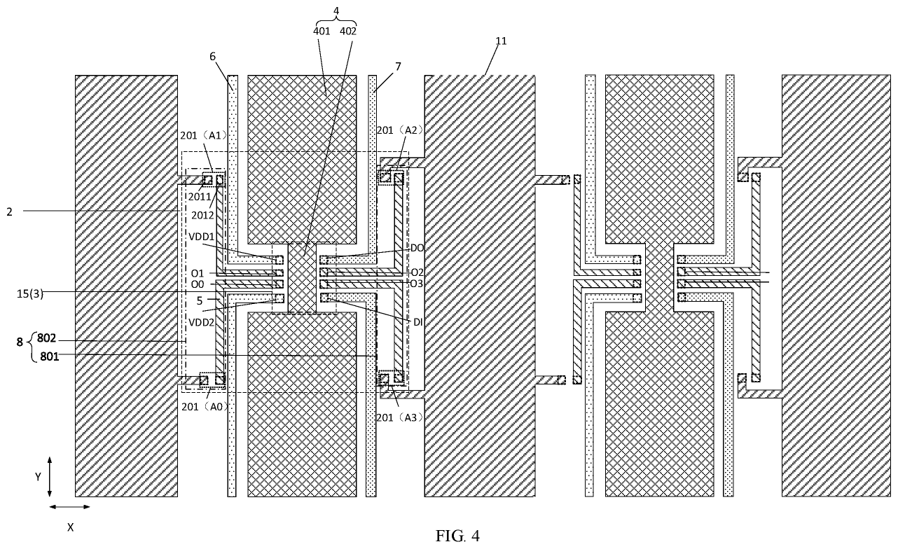

In some embodiments, as shown in FIG. 4, in the first direction X, only one constant voltage signal line 11 is included between adjacent two first unit columns 8, and the constant voltage signal line 11 disposed between the adjacent two first unit columns 8 is electrically connected to both first unit columns 8.

That is, in the wiring substrate according to some embodiments of the present disclosure, the adjacent two first unit columns share the same constant voltage signal line, and only one constant voltage signal line is required to be provided in the region between the adjacent two first unit columns. In this way, the width of the constant voltage signal line in the first direction is increased, such that the resistance of the constant voltage signal line is reduced, and thus the voltage drop of the constant voltage signal line is reduced.

In specific embodiments, the first pad region column and the second pad region column that are disposed in different first unit columns and adjacent to each other share the same constant voltage signal line.

In some embodiments, in the first direction, the width of the constant voltage signal line is equal to the width of the first section.

For example, in the first direction, the width of the constant voltage signal line and the width of the first portion are both 4500 micrometers.

It should be noted that in some practices, in the case where the constant voltage signal line and the common voltage signal line are disposed between adjacent two first unit columns, the width of the constant voltage signal line is about 1400 microns and the width of the common voltage signal line is about 2000 microns. In the wiring substrate according to some embodiments of the present disclosure, the common voltage signal line travels through the first unit and the second pad region, the constant voltage signal line is still disposed between adjacent two first unit columns, and the width of the constant voltage signal line and the width of the first portion are increased to 4500 microns. In a case where the thicknesses of the constant voltage signal line and the common voltage signal line are constant, the voltage drop is reduced.

In some embodiments, the common voltage signal line, the constant voltage signal line, the first pad group, and the second pad are disposed in the same layer.

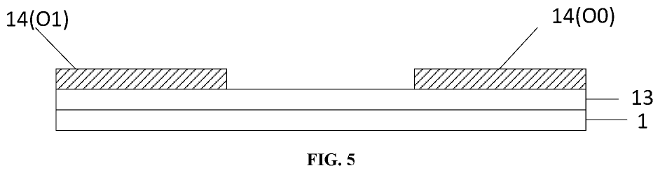

In specific embodiments, as shown in FIG. 5, the wiring substrate further includes a buffer layer 13 disposed on a side of the base substrate 1. In fabricating the wiring substrate, the buffer layer is first formed on a side of the base substrate, then a first conductive layer is formed on a side, facing away from the base substrate, of the buffer layer, and then patterns of the common voltage signal line, the constant voltage signal line, the first pad group, and the second pad are formed by using a patterning process. The base substrate is made of, for example, glass, quartz, plastic, polyimide, or the like. The buffer layer is made of, for example, silicon nitride. The first conductive layer is made of copper or aluminum with better conductivity.

It should be noted that only the output pads O0 and O1 included in the first conductive layer 14 are shown in FIG. 5. In specific implementations, a surface of a side, facing away from the buffer layer, of the first conductive layer is made of a conductive material with good antioxidation, such as a copper-nickel alloy, a nickel-tungsten alloy, a nickel-vanadium alloy, or the like. In this case, there is no need to provide an insulating protection layer on the side, backing facing from the buffer layer, of the first conductive layer. Accordingly, to enhance electrical reliability, the drive chip IC is an encapsulated circuit chip.

It should be understood that in some other embodiments, the side, facing away from the buffer layer, of the first conductive layer is provided with an insulating protection layer. The insulating protection layer has a plurality of openings therein. Regions, exposed by the openings of the protection layer, at both ends of the first connection lead are the first power pad and the second power pad, respectively. Regions, exposed by the openings of the protection layer, at both ends of the second connection lead are the first address pad and the second address pad, respectively. Regions, exposed by the openings of the protection layer, at both ends of the third connection lead are the output pad and the second sub-pad, respectively. Regions, exposed by the openings of the protection layer, at both ends of the fourth connection lead are the first sub-pad and the second sub-pad, respectively. A region, exposed by the openings of the insulating protection layer, of the constant voltage signal line is the first sub-pad. A region, exposed by the openings of the insulating protection layer, of the second portion is the ground pad.

Data related to the wiring substrate according to some embodiments of the present disclosure and the wiring substrate in some practices are illustrated hereinafter by way of example. The common voltage signal line and the constant voltage signal line are made of copper, with a thickness of 1.8 μm and a sheet resistance of 0.011 Ω/sq. In Scheme I and Scheme II, one drive chip drives four light-emitting devices to emit light, and in Scheme III and Scheme IV, one drive chip drives sixteen light-emitting devices to emit light. Scheme I and Scheme III use the wiring substrate according to some embodiments of the present disclosure, and a width of the constant voltage signal line is equal to a width of the first portion. Scheme II and Scheme IV use the wiring substrate according to some embodiments of the present disclosure, and a width of the constant voltage signal line is equal to a width of the first portion. A width of the constant voltage signal line of Scheme I is greater than a width of the constant voltage signal line of Scheme II, a width of the common voltage signal line of Scheme I is greater than a width of the common voltage signal line of Scheme II, a width of the constant voltage signal line of Scheme III is greater than a width of the constant voltage signal line of Scheme IV, and a width of the common voltage signal line of Scheme III is greater than a width of the common voltage signal line of Scheme IV. As listed in Table 1, a resistance of the common voltage signal line of Scheme I is 22% lower than a resistance of the common voltage signal line of Scheme II, a resistance of the constant voltage signal line of Scheme I is 69.2% lower than the resistance of the constant voltage signal line of Scheme II, a resistance of the common voltage signal line of Scheme III is 47% lower than a resistance of the common voltage signal line of Scheme IV, and a resistance of the constant voltage signal line of Scheme III is 69% lower than a resistance of the constant voltage signal line of Scheme IV. That is, in a case where the thickness of copper remains unchanged, compared to the wiring substrate in some practices, the wiring substrate according to some embodiments of the present application has a lower resistance of the common voltage signal line and a lower resistance of the constant voltage signal line, such that the voltage drop of the signal line is reduced.

TABLE 1

| | Signal line | Resistance/Ohm (Ω) |
|---|---|---|
| Scheme I | Common voltage signal line | 0.071 |
| | Constant voltage signal line | 0.040 |
| Scheme II | Common voltage signal line | 0.091 |
| | Constant voltage signal line | 0.130 |
| Scheme III | Common voltage signal line | 0.193 |
| | Constant voltage signal line | 0.162 |
| Scheme IV | Common voltage signal line | 0.364 |
| | Constant voltage signal line | 0.520 |

Some embodiments of the present disclosure provide an electronic device. The electronic device includes the wiring substrate according to some embodiments of the present disclosure, a plurality of electronic elements and a plurality of drive chips that are disposed on a side of the wiring substrate. The electronic element is electrically connected to the first pad group, and the drive chip is electrically connected to the second pad group.

In specific embodiments, the electronic element has two pins, and the two pins are respectively electrically connected to the first sub-pad and the second sub-pad of the first pad group. The drive chip includes a ground pin electrically connected to the ground pad, an output pin electrically connected to the output pad, a first address pin electrically connected to the first address pad, a second address pin electrically connected to the second address pad, a first power pin electrically connected to the first power pad, and a second power pin electrically connected to the second power pad. In a case where the second pad region includes four output pads, the drive chip includes four output pins.

In some embodiments, the electronic element is a micro-sized inorganic light-emitting diode.

In specific embodiments, the micro-sized inorganic light-emitting diode is, for example, a mini-light-emitting diode (Mini-LED) or a micro-light-emitting diode (Micro-LED). The Mini-LED and Micro-LED have small sizes and high brightness, and are widely used in display devices or their backlight modules. For example, a typical size (e.g., a length) of the Micro-LED is less than 100 microns, e.g., 10 microns to 80 microns, and a typical size (e.g., a length) of the Mini-LED is 80 microns to 350 microns, e.g., 80 microns to 120 microns. The electronic element is at least one of the Micro-LED or Mini-LED.

In specific embodiments, the electronic device is applied in the field of display. For example, the electronic device is used as a backlight of a display panel.

The electronic device according to some embodiments of the present disclosure includes the wiring substrate provided by the embodiments of the present disclosure, and thus for the implementation of the electronic device, reference is made to the embodiments of the wiring substrate described above, which is not repeated herein.

In summary, in the wiring substrate and the electronic device according to some embodiments of the present disclosure, the common voltage signal line travels through the first unit and the second pad region. Because the first unit has sufficient wiring space between two first pad regions adjacent in the first direction, the width, in the first direction, of the first common voltage signal line traveling through the first unit is arranged to be wide in the case of not interfering with the first pad region. That is, compared to the common voltage signal line arranged in the region between two first units adjacent in the first direction, the maximum width of the common voltage signal line in the first direction is increased, such that the resistance of the common voltage signal line is lowered, and thus the voltage drop of the common voltage signal line is lowered. In this way, the wiring substrate according to some embodiments of the present disclosure does not need to reduce the voltage drop by increasing the thickness of the common voltage signal line or double-layer wiring, such that the cost is saved. Moreover, the second portion, traveling through the second pad region, of the common voltage signal line is reused as the ground pad, and thus in a case where the electrical connection between the common voltage signal line and the ground pad is achieved, the wiring space is saved.

Although embodiments of the present invention have been described, those skilled in the art may make additional changes and modifications to these embodiments once the underlying inventive concepts are known. Therefore, the appended claims are intended to be construed to include the embodiments as well as all changes and modifications that fall within the scope of the present invention.

Those skilled in the art may make various changes and variations to the embodiments of the present invention without departing from the spirit and scope of the embodiments of the present invention. Thus, to the extent that such modifications and variations of the embodiments of the present invention fall within the scope of the claims of the present invention and their technical equivalents, the present invention is intended to encompass such modifications and variations.

1. A wiring substrate, comprising:
a base substrate;
a plurality of first units arranged in an array along a first direction and a second direction on a side of the base substrate, the first direction being intersected with the second direction, wherein each of the plurality of first units comprises a plurality of first pad regions, each of the plurality of first pad regions comprising at least one first pad group, the first pad group comprising a first sub-pad and a second sub-pad;
a plurality of second pad regions disposed on a same side of the base substrate as the plurality of first units, wherein each of the plurality of second pad regions comprises at least one second pad group, and the second pad group comprises a plurality of second pads, the plurality of second pads comprising ground pads and output pads in one-to-one correspondence to the plurality of first units, each the plurality of first units being connected to one of the output pads; and
a plurality of common voltage signal lines disposed on the same side of the base substrate as the plurality of first units, wherein the plurality of common voltage signal lines are arranged along the first direction and extend along the second direction, each of the plurality of common voltage signal lines travels through the first unit and the second pad region, and each of the plurality of common voltage signal lines comprises a plurality of first portions and a plurality of second portions, wherein the first portions and the second portions are successively alternately connected in the second direction, a width of each of the first portions is greater than a width of each of the second portions in the first direction, and each of the second portions travels through the second pad region and is reused as the ground pad.

2. The wiring substrate according to claim 1, wherein the second pad region is disposed within the first unit, and an orthographic projection of the second pad group on the base substrate is not overlapped with an orthographic projection of the first pad region on the base substrate.

3. The wiring substrate according to claim 2, wherein the first portion has a first axis of symmetry extending along the second direction, and the second portion has a second axis of symmetry extending along the second direction, the first axis of symmetry being coincident with the second axis of symmetry.

4. The wiring substrate according to claim 1, wherein
the plurality of second pads further comprise a first power pad, a second power pad, a first address pad, and a second address pad; and
the rest of the second pads other than the ground pad are disposed on two sides of the ground pad in the first direction.

5. The wiring substrate according to claim 4, wherein the first power pad, the second power pad, and one portion of the output pads are disposed on one side of the second portion in the first direction, and the first address pad, the second address pad, and the other portion of the output pads are disposed on the other side of the second portion in the first direction.

6. The wiring substrate according to claim 5, wherein
the first power pad, the second power pad, and the portion of the output pads are arranged along the second direction, and in the second direction, the first power pad and the second power pad are disposed on two sides of the portion of the output pads, respectively; and
the first address pad, the second address pad, and the other portion of the output pads are arranged along the second direction, and in the second direction, the first address pad and the second address pad are disposed on two sides of the other portion of the output pads, respectively.

7. The wiring substrate according to claim 5, further comprising: a plurality of first connection leads, a plurality of second connection leads, and a plurality of third connection leads; wherein
in the second direction, one end of the first connection lead is electrically connected to the first power pad of one of adjacent two of the second pad regions, and the other end of the first connection lead is electrically connected to the second power pad of the other of the adjacent two second pad regions;
in the second direction, one end of the second connection lead is electrically connected to the first address pad of one of adjacent two of the second pad regions, and the other end of the second connection lead is electrically connected to the second address pad of the other of the adjacent two second pad regions; and
one end of the third connection lead is electrically connected to the output pad, and the other end of the third connection lead is electrically connected to the first pad region.

8. The wiring substrate according to claim 7, wherein
the first connection lead is disposed between the third connection lead and the common voltage signal line; and
the second connection lead is disposed between the third connection lead and the common voltage signal line.

9. The wiring substrate according to claim 1, wherein each of the first pad regions comprises a plurality of the first pad groups connected in series.

10. The wiring substrate according to claim 9, wherein the plurality of the first pad groups connected in series are successively arranged along the second direction.

11. The wiring substrate according to claim 1, wherein the plurality of first units successively arranged along the second direction form a first unit column; and
the wiring substrate further comprises:
a plurality of constant voltage signal lines disposed on the same side of the base substrate as the plurality of first units, wherein the plurality of constant voltage signal lines are arranged along the first direction and extend along the second direction, are disposed on a side of the first unit column, and are electrically connected to at least one of the first unit columns.

12. The wiring substrate according to claim 11, wherein in the first direction, only one of the constant voltage signal lines is present between adjacent two of the first unit columns, and the constant voltage signal line disposed between adjacent two of the first unit columns is electrically connected to the adjacent two first unit columns.

13. The wiring substrate according to claim 11, wherein in the first direction, a width of the constant voltage signal line is equal to the width of the first portion.

14. The wiring substrate according to claim 1, wherein in the first direction, a ratio of the width of the second portion to the width of the first portion is greater than or equal to ⅕ and less than 1.

15. An electronic device, comprising: a wiring substrate, a plurality of electronic elements and a plurality of drive chips that are disposed on a side of the wiring substrate; wherein
the wiring substrate comprises:
a base substrate;
a plurality of first units arranged in an array along a first direction and a second direction on a side of the base substrate, the first direction being intersected with the second direction, wherein each of the plurality of first units comprises a plurality of first pad regions, each of the plurality of first pad regions comprising at least one first pad group, the first pad group comprising a first sub-pad and a second sub-pad;
a plurality of second pad regions disposed on a same side of the base substrate as the plurality of first units, wherein each of the plurality of second pad regions comprises at least one second pad group, and the second pad group comprises a plurality of second pads, the plurality of second pads comprising ground pads and output pads in one-to-one correspondence to the plurality of first units, each the plurality of first units being connected to one of the output pads; and
a plurality of common voltage signal lines disposed on the same side of the base substrate as the plurality of first units, wherein the plurality of common voltage signal lines are arranged along the first direction and extend along the second direction, each of the plurality of common voltage signal lines travels through the first unit and the second pad region, and each of the plurality of common voltage signal lines comprises a plurality of first portions and a plurality of second portions, wherein the first portions and the second portions are successively alternately connected in the second direction, a width of each of the first portions is greater than a width of each of the second portions in the first direction, and each of the second portions travels through the second pad region and is reused as the ground pad; and
each of the plurality of electronic elements is electrically connected to the first pad group, and each of the plurality of drive chips is electrically connected to the second pad group.

16. The electronic device according to claim 15, wherein the electronic elements are micro-sized inorganic light-emitting diodes.

17. The electronic device according to claim 15, wherein the second pad region is disposed within the first unit, and an orthographic projection of the second pad group on the base substrate is not overlapped with an orthographic projection of the first pad region on the base substrate.

18. The electronic device according to claim 17, wherein the first portion has a first axis of symmetry extending along the second direction, and the second portion has a second axis of symmetry extending along the second direction, the first axis of symmetry being coincident with the second axis of symmetry.

19. The electronic device according to claim 15, wherein
the plurality of second pads further comprise a first power pad, a second power pad, a first address pad, and a second address pad; and
the rest of the second pads other than the ground pad are disposed on two sides of the ground pad in the first direction.

20. The electronic device according to claim 19, wherein the first power pad, the second power pad, and one portion of the output pads are disposed on one side of the second portion in the first direction, and the first address pad, the second address pad, and the other portion of the output pads are disposed on the other side of the second portion in the first direction.
